(19) United States
(12) Patent Application Publication
(10) Pub. No.: US 2025/0257242 A1
(43) Pub. Date: Aug. 14, 2025

(54) CMP POLISHING LIQUID AND POLISHING METHOD

(71) Applicant: Resonac Corporation, Tokyo (JP)

(72) Inventor: Hiroshi ONO, Tokyo (JP)

(21) Appl. No.: 18/856,465

(22) PCT Filed: Jun. 12, 2023
(86) PCT No.: PCT/JP2023/021766

§ 371 Date: Oct. 11, 2024

(30) Foreign Application Priority Data
Jun. 15, 2022 (JP) 2022-096296

(51) Int. Cl. C09G 1/02; B24B 37/04; H01L 21/3105

(52) U.S. Cl. CPC C09G 1/02; B24B 37/044; H01L 21/31053

(57) ABSTRACT

A CMP polishing liquid for polishing a carbon material, in which the CMP polishing liquid contains abrasive grains, iron ions, and water, the abrasive grains contain silica, a content of the iron ions is 7 ppm or more, and a pH is 3.5 or less. A polishing method including polishing a carbon material by using the CMP polishing liquid.

### TECHNICAL FIELD

The present disclosure relates to a CMP polishing liquid, a polishing method, and the like.

### BACKGROUND ART

In recent years, along with higher integration or higher performance of semiconductor integrated circuits (LSI), new microfabrication technologies have been developed. For the purpose of miniaturization, it is necessary to improve a lithography technique for transferring a pattern to a semiconductor substrate, however, in the case of forming a narrow and deep groove (for example, 3D NAND memory through-hole) with a high aspect ratio, a resist mask using a photosensitive resin or the like may not be able to withstand etching during groove formation. Therefore, there is a case where a hard mask is used instead of the resist mask. The hard mask has higher resistance to etching than the resist mask, and can withstand etching for a long time during groove formation.

An example of a process of obtaining a hard mask used during etching is as follows. First, a member A used for obtaining a hard mask is formed on a workpiece, and a member B used for obtaining a resist mask is then formed on the member A. Subsequently, the member B is patterned using a reticle to obtain a resist mask, and the member A is then etched and patterned using this resist mask to obtain a hard mask.

As a constituent material of the hard mask, a carbon material such as amorphous carbon may be used. A lithography technique using such a carbon material as the constituent material of the hard mask is described, for example, in Patent Literatures 1 and 2 below.

In a case where dust is mixed from the outside of an apparatus for obtaining the hard mask or a case where dust has been mixed in a material used for obtaining the hard mask, the dust may adhere to or be embedded in a surface of the hard mask. Due to this dust, the accuracy of a shape of the hard mask may be decreased, and the processing accuracy during etching may be decreased. As a method for removing dust on a surface of a hard mask, for example, Patent Literature 3 below describes a technique of removing a surface layer of a hard mask by using chemical mechanical polishing (hereinafter, referred to as “CMP”).

### CITATION LIST

### Patent Literatures

Patent Literature 1: Japanese Unexamined Patent Publication No. 2007-523034

Patent Literature 2: Japanese Unexamined Patent Publication No. 2013-26305

Patent Literature 3: Japanese Unexamined Patent Publication No. 2010-135543

### SUMMARY OF INVENTION

### Technical Problem

However, since the polishing rate of a carbon material tends to be very low, there is a case where it is difficult to apply CMP to a hard mask using the carbon material. Therefore, for the CMP polishing liquid, it is demanded to polish the carbon material at a high polishing rate.

An object of an aspect of the present disclosure is to provide a CMP polishing liquid capable of polishing a carbon material at a high polishing rate. In addition, an object of another aspect of the present disclosure is to provide a polishing method using such CMP polishing liquid.

### Solution to Problem

The present disclosure relates to the following [1] to [13] and the like in some aspects.
[1] A CMP polishing liquid for polishing a carbon material, the CMP polishing liquid containing abrasive grains, iron ions, and water, in which the abrasive grains contain silica, a content of the iron ions is 7 ppm or more, and a pH is 3.5 or less.
[2] The CMP polishing liquid according to [1], in which the content of the iron ions is 15 to 250 ppm.
[3] The CMP polishing liquid according to [1] or [2], further containing an oxidizing agent.
[4] The CMP polishing liquid according to [3], in which the oxidizing agent includes a peroxide.
[5] The CMP polishing liquid according to [3] or [4], in which a content of the oxidizing agent is 2 mass % or more.
[6] The CMP polishing liquid according to any one of [1] to [5], further containing an organic acid component.
[7] The CMP polishing liquid according to [6], in which the organic acid component includes at least one selected from the group consisting of a divalent organic acid component and a trivalent organic acid component as an organic acid component having no carbon-carbon unsaturated bond.
[8] The CMP polishing liquid according to [6] or [7], in which a content of the organic acid component is 0.1 mass % or more.
[9] The CMP polishing liquid according to any one of [1] to [8], further containing an organic solvent.
[10] The CMP polishing liquid according to [9], in which the organic solvent includes a glycol monoether.
[11] The CMP polishing liquid according to [9] or [10], in which the organic solvent includes a propylene glycol monopropyl ether.
[12] The CMP polishing liquid according to any one of [1] to [11], in which the carbon material includes amorphous carbon.
[13] A polishing method including polishing a carbon material by using the CMP polishing liquid according to any one of [1] to [12].

### Advantageous Effects of Invention

According to an aspect of the present disclosure, it is possible to provide a CMP polishing liquid capable of polishing a carbon material at a high polishing rate. In addition, according to another aspect of the present disclosure, it is possible to provide a polishing method using such CMP polishing liquid.

### DESCRIPTION OF EMBODIMENTS

Hereinafter, embodiments of the present disclosure will be described.

In the present specification, a numerical range indicated using “to” indicates a range including numerical values described before and after “to” as a minimum value and a maximum value, respectively. “A or more” of a numerical range means A and a range exceeding A. “A or less” of a numerical range means A and a range less than A. In a numerical range described stepwise in the present specification, an upper limit value or a lower limit value of a numerical range of a certain stage can be arbitrarily combined with an upper limit value or a lower limit value of a numerical range of another stage. In a numerical range described in the present specification, the upper limit value or the lower limit value of the numerical range may be replaced with a value shown in Examples. “A or B” may include either A or B, and may include both A and B. The materials exemplified in the present specification can be used alone or in combination of two or more thereof unless otherwise specified. When a plurality of materials corresponding to the respective components are present in the composition, a content of each component in the composition means the total amount of the plurality of materials present in the composition unless otherwise specified. The term “step” includes not only an independent step but also a step that cannot be clearly distinguished from other steps as long as the intended action of the step is achieved.

A CMP polishing liquid (hereinafter, simply referred to as a “polishing liquid”) of the present embodiment is a polishing liquid for polishing a carbon material (a polishing liquid for a carbon material), and can be used for polishing a surface to be polished containing a carbon material. The carbon material is a carbon-containing material that contains carbon atoms. As the carbon material, a material in which carbon atoms constitute at least one-third of all the atoms constituting the carbon material (a content of carbon atoms is 33 atm % or more based on the total amount of atoms constituting the carbon material) can be used. Examples of the carbon material include amorphous carbon (diamond-like carbon (DLC)); and resin materials such as an epoxy resin, a polyimide resin, an acrylic resin (a polymer having a structural unit derived from a monomer having a (meth)acryloyl group), and a polybenzoxazole resin. The carbon material may have a carbon-carbon bond. The carbon material may be a non-photosensitive resin (resin not having photosensitivity), and may be a resin that is not a cured product of a photosensitive resin. The carbon material may be a material that does not contain at least one selected from the group consisting of silicon oxide particles, a crosslinking agent (for example, a vinyl ether crosslinking agent), and a photoinitiator (photopolymerization initiator).

Amorphous carbon is a material mainly constituted of carbon atoms, with SP3 bonds and SP2 bonds mixed. The amorphous carbon may be referred to as diamond-like carbon. The amorphous carbon may contain other atoms such as a hydrogen atom, a boron atom, or a silicon atom in addition to a carbon atom. As a method for forming a film of amorphous carbon, a chemical vapor deposition method (CVD method), a spin coating method, or the like can be used.

The Vickers hardness of the carbon material may be 100 HV or more, 200 HV or more, 300 HV or more, 400 HV or more, or 500 HV or more. The Vickers hardness of the carbon material may be 1000 HV or less, 900 HV or less, 800 HV or less, 700 HV or less, 600 HV or less, or 500 HV or less. From these viewpoints, the Vickers hardness of the carbon material may be 100 to 1000 HV, 100 to 800 HV, 100 to 600 HV, 300 to 1000 HV, 300 to 800 HV, 300 to 600 HV, 400 to 1000 HV, 400 to 800 HV, or 400 to 600 HV.

The polishing liquid of the present embodiment contains abrasive grains, iron ions, and water, in which the abrasive grains contain silica, the content of the iron ions is 7 ppm or more, and a pH of the polishing liquid is 3.5 or less. According to the polishing liquid of the present embodiment, the carbon material can be polished at a high polishing rate. According to the polishing liquid of the present embodiment, for example, a polishing rate of 0.8 nm/min or more (preferably 0.9 nm/min or more) can be obtained in the evaluation described in Examples described later.

The reason for obtaining the effect that the carbon material can be polished at a high polishing rate is unclear, but the following reasons are exemplified. Note that, the reason for obtaining the above-described effect is not limited to the following contents. That is, a sufficient amount of the iron ions (the iron ions having the content described above) oxidizes the carbon material to break a molecular chain (carbon-carbon bond or the like) of the carbon material, thereby reducing the mechanical strength of the carbon material. In addition, it is presumed that, in a case where the pH is within the above range, the carbon material can be polished at a high polishing rate by polishing the carbon material in such a state with the abrasive grains containing silica.

The polishing liquid of the present embodiment can be used, for example, for polishing in a wiring forming step of a semiconductor device, and the like. The polishing liquid of the present embodiment can be suitably used not only for polishing the carbon material used as a constituent material of the hard mask, but also for polishing an interlayer insulating film using the carbon material.

The polishing liquid of the present embodiment contains abrasive grains containing silica. Examples of the abrasive grains include colloidal silica, amorphous silica, crystalline silica, fused silica, spherical silica, synthetic silica, and hollow silica. The abrasive grains may contain colloidal silica from the viewpoint of easily polishing the carbon material at a high polishing rate and the viewpoint of hardly generating defects such as scratches on a polished surface of an object to be polished and easily improving the flatness of the polished surface.

The average particle diameter of the abrasive grains may be 10 nm or more, 15 nm or more, 20 nm or more, 25 nm or more, 30 nm or more, 35 nm or more, 40 nm or more, 45 nm or more, 50 nm or more, 55 nm or more, or 60 nm or more, from the viewpoint of easily polishing the carbon material at a high polishing rate because it is easy to ensure sufficient physical polishing ability per abrasive grain. The average particle diameter of the abrasive grains may be 200 nm or less, 190 nm or less, 180 nm or less, 150 nm or less, 120 nm or less, 100 nm or less, 80 nm or less, or 70 nm or less, from the viewpoint of easily polishing the carbon material at a high polishing rate because the number of abrasive grains per unit area in contact with the surface to be polished is easily and sufficiently ensured. From these viewpoints, the average particle diameter of the abrasive grains may be 10 to 200 nm, 10 to 100 nm, 10 to 80 nm, 15 to 190 nm, 20 to 180 nm, 30 to 100 nm, 30 to 200 nm, 30 to 80 nm, 50 to 200 nm, 50 to 100 nm, or 50 to 80 nm.

The “average particle diameter” is a secondary particle diameter of the abrasive grains, and can be obtained by measuring a particle diameter of the abrasive grains in the polishing liquid or a particle diameter of the abrasive grains before being blended in the polishing liquid. The average particle diameter can be measured by a light diffraction scattering particle diameter distribution analyzer, and may be measured by preparing a sample in which the abrasive grains are dispersed in water. For example, the measurement can be carried out using COULTER N4SD manufactured by Coulter Electronics, Inc. under the conditions as follows: a measurement temperature of 20° C., a solvent refractive index of 1.333 (water), a particle refractive index of Unknown (setting), a solvent viscosity of 1.005 cp (water), Run Time of 200 seconds, a laser incident angle of 90°, and Intensity (corresponding to scattering intensity and turbidity) of 5E+04 to 4E+05, and the measurement can be carried out by diluting the sample with water in a case where the Intensity is higher than 4E+05. Since colloidal particles are usually obtained in a state of being dispersed in water, the measurement can be carried by appropriately diluting the colloidal particles to fall within the above-described range of scattering intensity.

A content of the silica in the abrasive grains may be 50 mass % or more, more than 50 mass %, 60 mass % or more, 70 mass % or more, 80 mass % or more, 90 mass % or more, 95 mass % or more, 98 mass % or more, or 99 mass % or more, based on the total mass of the abrasive grains (the entire abrasive grains contained in the polishing liquid) from the viewpoint of easily polishing the carbon material at a high polishing rate. The abrasive grains may have a form composed of silica (substantially 100 mass % of the abrasive grains contained in the polishing liquid is silica).

The polishing liquid of the present embodiment may not contain zirconia particles, and the abrasive grains may not contain zirconia. A content of the zirconia particles may be 0.01 mass % or less, less than 0.01 mass %, 0.001 mass % or less, or 0.0001 mass % or less, based on the total mass of the polishing liquid.

A content of the abrasive grains may be within the following range based on the total mass of the polishing liquid. The content of the abrasive grains may be 0.01 mass % or more, 0.02 mass % or more, 0.05 mass % or more, 0.1 mass % or more, 0.2 mass % or more, 0.3 mass % or more, 0.35 mass % or more, or 0.4 mass % or more, from the viewpoint of easily polishing the carbon material at a high polishing rate. The content of the abrasive grain may be 20 mass % or less, 15 mass % or less, 10 mass % or less, 5 mass % or less, 3 mass % or less, 2 mass % or less, 1 mass % or less, 0.8 mass % or less, 0.5 mass % or less, or 0.4 mass % or less, from the viewpoint of suppressing the occurrence of scratches. From these viewpoints, the content of the abrasive grains may be 0.01 to 20 mass %, 0.01 to 10 mass %, 0.01 to 5 mass %, 0.01 to 1 mass %, 0.02 to 15 mass %, 0.05 to 20 mass %, 0.05 to 10 mass %, 0.05 to 5 mass %, 0.05 to 1 mass %, 0.1 to 20 mass %, 0.1 to 10 mass %, 0.1 to 5 mass %, 0.1 to 1 mass %, 0.3 to 20 mass %, 0.3 to 10 mass %, 0.3 to 5 mass %, or 0.3 to 1 mass %.

The polishing liquid of the present embodiment contains iron ions. The iron ions may include ferric ions (Fe³⁺) from the viewpoint of easily polishing the carbon material at a high polishing rate.

It is possible to obtain a polishing liquid containing iron ions by obtaining the polishing liquid using an iron ion-supplying agent. The polishing liquid of the present embodiment may contain an iron ion-supplying agent. The iron ion-supplying agent supplies iron ions in the polishing liquid.

Examples of the iron ion-supplying agent include salts of iron ions and hydrates of these salts. The salts of iron ions may include at least one selected from the group consisting of inorganic salts and organic salts. Examples of the inorganic salts include iron nitrate, iron sulfate, iron boride, iron chloride, iron bromide, iron iodide, iron phosphate, and iron fluoride. Examples of the organic salts include iron triformate, iron diformate, iron acetate, iron propionate, iron oxalate, iron malonate, iron succinate, iron malate, iron glutarate, iron tartrate, iron lactate, and iron citrate. The salts (inorganic salts, organic salts, or the like) of iron ions may contain a ligand such as ammonium or water.

In the polishing liquid containing the iron ion-supplying agent, the iron ion-supplying agent may exist in a state of being dissociated into iron ions and anions derived from the iron ion-supplying agent. The polishing liquid of the present embodiment may contain nitrate ions from the viewpoint of easily polishing the carbon material at a high polishing rate. The polishing liquid of the present embodiment may contain at least one selected from the group consisting of iron nitrate and iron nitrate hydrates from the viewpoint of easily polishing the carbon material at a high polishing rate, the viewpoint of relatively less contamination in a polishing apparatus, a base substrate, or the like, and the viewpoint of being low-cost and easily available.

A content of the iron ions is 7 ppm or more based on the total mass of the polishing liquid from the viewpoint of polishing the carbon material at a high polishing rate. The content of the iron ions may be within the following range based on the total mass of the polishing liquid. From the viewpoint of easily polishing the carbon material at a high polishing rate, the content of the iron ions may be 8 ppm or more, 10 ppm or more, 15 ppm or more, 20 ppm or more, 25 ppm or more, 30 ppm or more, 35 ppm or more, 40 ppm or more, 50 ppm or more, 80 ppm or more, 100 ppm or more, 120 ppm or more, 130 ppm or more, 140 ppm or more, 150 ppm or more, 180 ppm or more, 200 ppm or more, 220 ppm or more, 250 ppm or more, or 270 ppm or more. The content of the iron ions may be 1000 ppm or less, 800 ppm or less, 600 ppm or less, 500 ppm or less, 400 ppm or less, 300 ppm or less, 280 ppm or less, 270 ppm or less, 250 ppm or less, 220 ppm or less, 200 ppm or less, 180 ppm or less, 150 ppm or less, 140 ppm or less, 130 ppm or less, 120 ppm or less, 100 ppm or less, 80 ppm or less, 50 ppm or less, 40 ppm or less, 35 ppm or less, 30 ppm or less, 25 ppm or less, 20 ppm or less, or 15 ppm or less. From these viewpoints, the content of the iron ions may be 7 to 1000 ppm, 7 to 300 ppm, 7 to 250 ppm, 15 to 1000 ppm, 15 to 300 ppm, 15 to 250 ppm, 50 to 1000 ppm, 50 to 300 ppm, 50 to 250 ppm, 100 to 1000 ppm, 100 to 300 ppm, 100 to 250 ppm, 200 to 1000 ppm, or 200 to 300 ppm. A content of the iron ion-supplying agent may be adjusted so that the content of the iron ions in the polishing liquid falls within the above-described ranges. In a case where a content (unit: ppm) of the iron ions is converted into a content (unit: mM), the polishing liquid may adopt a specific gravity of 1. The content of the iron ions of 7 to 1000 ppm can be converted into 0.126 to 18 mM.

A mass ratio of the content of the iron ions with respect to the content of the abrasive grains (iron ions/abrasive grains) may be within the following range. The mass ratio may be 0.001 or more, 0.003 or more, 0.004 or more, 0.005 or more, 0.006 or more, 0.007 or more, 0.008 or more, 0.01 or more, 0.02 or more, 0.03 or more, 0.04 or more, 0.05 or more, or 0.06 or more, from the viewpoint of easily polishing the carbon material at a high polishing rate. The mass ratio may be 0.1 or less, 0.08 or less, or 0.07 or less, from the viewpoint of easily polishing the carbon material at a high polishing rate. The mass ratio may be 0.06 or less, 0.05 or less, 0.04 or less, 0.03 or less, 0.02 or less, 0.01 or less, 0.008 or less, 0.007 or less, 0.006 or less, 0.005 or less, or 0.004 or less. From these viewpoints, the mass ratio may be 0.001 to 0.1, 0.001 to 0.08, 0.001 to 0.05, 0.005 to 0.1, 0.005 to 0.08, 0.005 to 0.05, 0.01 to 0.1, 0.01 to 0.08, or 0.01 to 0.05.

The polishing liquid of the present embodiment may contain an oxidizing agent (an oxidizing agent for the carbon material; excluding compounds corresponding to iron ions or compounds containing iron ions). The carbon material is further oxidized using the oxidizing agent, resulting in an improved polishing rate of the carbon material. In a case where the oxidizing agent is used in the absence of iron ions, the effect of improving the polishing rate of the carbon material cannot be obtained, however, in a case where the oxidizing agent is used in the presence of iron ions, the polishing rate of the carbon material can be improved.

Examples of the oxidizing agent include hydrogen peroxide, nitric acid, potassium periodate, hypochlorous acid, and ozone water. In a case where the base substrate to be polished is a silicon substrate having an integrated circuit element, the oxidizing agent may include an oxidizing agent containing no nonvolatile component and may include hydrogen peroxide, from the viewpoint of avoiding contamination with an alkali metal, an alkaline earth metal, a halide, or the like. The oxidizing agent may include a peroxide and may include hydrogen peroxide, from the viewpoint of easily polishing the carbon material at a high polishing rate. As the oxidizing agent, a compound having a weaker oxidation-reduction potential than iron ions can be used.

A content of the oxidizing agent may be within the following range based on the total mass of the polishing liquid. The content of the oxidizing agent may be 0.1 mass % or more, 0.5 mass % or more, 1 mass % or more, 1.5 mass % or more, 1.7 mass % or more, 2 mass % or more, 2.5 mass % or more, or 3 mass % or more, from the viewpoint of easily polishing the carbon material at a high polishing rate. The content of the oxidizing agent may be 20 mass % or less, 15 mass % or less, 10 mass % or less, 8 mass % or less, 6 mass % or less, 5 mass % or less, 4 mass % or less, or 3 mass % or less. From these viewpoints, the content of the oxidizing agent may be 0.1 to 20 mass %, 0.1 to 10 mass %, 0.1 to 5 mass %, 1 to 20 mass %, 1 to 10 mass %, 1 to 5 mass %, 2 to 20 mass %, 2 to 10 mass %, or 2 to 5 mass %.

A mass ratio of the content of the oxidizing agent with respect to the content of the abrasive grains (oxidizing agent/abrasive grains) may be within the following range from the viewpoint of easily polishing the carbon material at a high polishing rate. The mass ratio may be 0.1 or more, 0.5 or more, 1 or more, 2 or more, 3 or more, 4 or more, 5 or more, 6 or more, 7 or more, or 7.5 or more. The mass ratio may be 50 or less, 40 or less, 30 or less, 20 or less, 15 or less, 10 or less, 9 or less, 8 or less, or 7.5 or less. From these viewpoints, the mass ratio may be 0.1 to 50, 0.1 to 30, 0.1 to 10, 1 to 50, 1 to 30, 1 to 10, 5 to 50, 5 to 30, or 5 to 10.

A mass ratio of the content of the oxidizing agent with respect to the content of the iron ions (oxidizing agent/iron ions) may be within the following range. The mass ratio may be 10 or more, 30 or more, 50 or more, 80 or more, or 100 or more, from the viewpoint of easily polishing the carbon material at a high polishing rate. The mass ratio may be 120 or more, 150 or more, 180 or more, 200 or more, 250 or more, 300 or more, 500 or more, 800 or more, 1000 or more, 1500 or more, or 2000 or more. The mass ratio may be 3000 or less, 2500 or less, 2000 or less, 1500 or less, 1000 or less, 800 or less, 500 or less, 300 or less, 250 or less, 200 or less, 180 or less, 150 or less, or 120 or less, from the viewpoint of easily polishing the carbon material at a high polishing rate. From these viewpoints, the mass ratio may be 10 to 3000, 10 to 2000, 10 to 500, 10 to 200, 100 to 3000, 100 to 2000, 100 to 500, 100 to 200, 200 to 3000, 200 to 2000, 200 to 500, 500 to 3000, or 500 to 2000.

The polishing liquid of the present embodiment may contain an acid component (excluding compounds corresponding to compounds containing iron ions or oxidizing agents). The acid component can be used as a pH adjusting agent for adjusting the pH of the polishing liquid. Examples of the acid component include an inorganic acid component and an organic acid component. Examples of the inorganic acid component include inorganic acids (such as sulfuric acid, hydrochloric acid, and phosphoric acid) and salts thereof (such as alkali metal salts and ammonium salts). Examples of the organic acid component include organic acids and salts thereof (for example, alkali metal salts such as a sodium salt; and alkaline earth metal salts such as a calcium salt).

As described above, the polishing liquid of the present embodiment can contain the oxidizing agent such as hydrogen peroxide. In such a polishing liquid, there is a possibility that the decomposition of the oxidizing agent proceeds by the interaction between the iron ions and the oxidizing agent (such as hydrogen peroxide) and the storage stability of the polishing liquid is impaired. On the other hand, such decomposition of the oxidizing agent can be inhibited by using an organic acid component. From such a viewpoint, the acid component may include an organic acid component.

The reason why the above-described effect can be obtained by the organic acid component is unclear, but it is presumed that the organic acid component is dissociated in the polishing liquid, and the dissociated organic acid component chelates iron ions, thereby inhibiting the decomposition of the oxidizing agent due to the iron ions. Note that, the reason for obtaining the above-described effect is not limited to these contents. The term “dissociation” means that a cation (for example, a proton (H⁺)) is separated from at least one acid group (for example, a carboxy group (—COOH)) of the organic acid component in the polishing liquid, resulting in the acid group being present in the state of an anionic group (for example, —COO⁻). The organic acid component may include at least one selected from the group consisting of a carboxyl group and a carboxylic acid salt group as an acid group from the viewpoint of easily obtaining the above-described effect.

The organic acid component may include an organic acid component having no carbon-carbon unsaturated bond from the viewpoint of easily maintaining the oxidizing agent more stably and easily stabilizing the polishing rate of the carbon material. The reason why the stability of the oxidizing agent is improved when the organic acid component has no carbon-carbon unsaturated bond is unclear, but it is presumed as one factor that, since the reactivity of the carbon-carbon unsaturated bond is relatively high, the organic acid component having no carbon-carbon unsaturated bond is less likely to cause deterioration due to a reaction between the oxidizing agent and the organic acid component in the polishing liquid. Note that, the reason for obtaining the above-described effect is not limited to these contents.

The organic acid component may include at least one selected from the group consisting of a divalent organic acid component and a trivalent organic acid component. The term “divalent” or “trivalent” means the number of acid groups contained in the organic acid component. It is considered that, when the organic acid component is divalent or trivalent, iron ions are chelated by a plurality of acid groups (for example, two or more dissociated acid groups, a dissociated acid group and an undissociated acid group, or the like) contained in the organic acid component, and the oxidizing agent tends to be more stably maintained.

The organic acid component may include an organic acid component having a dissociation rate at pH 2.5 of 1% or more. Since the dissociated organic acid component is effective for chelating iron ions, the required amount of the organic acid component can be reduced in a case where the dissociation rate is 1% or more. From the same viewpoint, the dissociation rate of the organic acid component at pH 2.5 may be 3% or more, 5% or more, 10% or more, 12% or more, or 15% or more. The dissociation rate of the organic acid component at pH 2.5 may be 50% or less, 30% or less, 20% or less, 18% or less, or 16% or less. From these viewpoints, the dissociation rate of the organic acid component at pH 2.5 may be 1% to 50%, 3% to 50%, 10% to 50%, 1% to 30%, 3% to 30%, 10% to 30%, 1% to 20%, 3% to 20%, or 10% to 20%.

From the above-described viewpoint, the organic acid component may include at least one selected from the group consisting of a divalent organic acid component and a trivalent organic acid component as an organic acid component having no carbon-carbon unsaturated bond, and may include at least one selected from the group consisting of a divalent organic acid component and a trivalent organic acid component as an organic acid component having no carbon-carbon unsaturated bond and having a dissociation rate at pH 2.5 of 1% or more.

Examples of the organic acid include malonic acid (dissociation rate at pH 2.5: 41.4%), succinic acid (dissociation rate at pH 2.5: 3.1%), glutaric acid (dissociation rate at pH 2.5: 1.4%), adipic acid (dissociation rate at pH 2.5: 1.7%), malic acid (dissociation rate at pH 2.5: 15.4%), and citric acid (dissociation rate at pH 2.5: 19.0%). The organic acid component may include at least one selected from the group consisting of malonic acid, succinic acid, glutaric acid, adipic acid, malic acid, citric acid, and salts thereof, from the viewpoint of easily polishing the carbon material at a high polishing rate.

A content of the acid component or a content of the organic acid component may be within the following range based on the total mass of the polishing liquid, from the viewpoint of easily polishing the carbon material at a high polishing rate. The content of the acid component or the content of the organic acid component may be 0.01 mass % or more, 0.05 mass % or more, 0.1 mass % or more, 0.2 mass % or more, 0.3 mass % or more, 0.4 mass % or more, or 0.5 mass % or more. The content of the acid component or the content of the organic acid component may be 10 mass % or less, 5 mass % or less, 3 mass % or less, 1 mass % or less, 0.8 mass % or less, or 0.5 mass % or less. From these viewpoints, the content of the acid component or the content of the organic acid component may be 0.01 to 10 mass %, 0.01 to 5 mass %, 0.01 to 1 mass %, 0.05 to 10 mass %, 0.05 to 5 mass %, 0.05 to 1 mass %, 0.1 to 10 mass %, 0.1 to 5 mass %, or 0.1 to 1 mass %.

The ratio of the number of molecules of the dissociated organic acid component with respect to one atom of iron ions may be 1.5 or more, 4 or more, or 6 or more, from the viewpoint of easily and sufficiently chelating iron ions and easily enhancing the stability of the oxidizing agent. The number of molecules of the dissociated organic acid component can be calculated from the dissociation rate of the organic acid component. The dissociation rate of the organic acid component can be calculated based on the pH of the polishing liquid and the acid dissociation constant of the organic acid component.

A mass ratio of the content of the acid component with respect to the content of the abrasive grains (acid component/abrasive grains) or a mass ratio of the content of the organic acid component with respect to the content of the abrasive grains (organic acid component/abrasive grains) may be within the following range, from the viewpoint of easily polishing the carbon material at a high polishing rate. The mass ratio may be 0.1 or more, 0.3 or more, 0.5 or more, 0.8 or more, 1 or more, or 1.2 or more. The mass ratio may be 5 or less, 4 or less, 3 or less, 2 or less, 1.8 or less, 1.5 or less, or 1.3 or less. From these viewpoints, the mass ratio may be 0.1 to 5, 0.1 to 3, 0.1 to 1.5, 0.5 to 5, 0.5 to 3, 0.5 to 1.5, 1 to 5, 1 to 3, or 1 to 1.5.

A mass ratio of the content of the acid component with respect to the content of the oxidizing agent (acid component/oxidizing agent) or a mass ratio of the content of the organic acid component with respect to the content of the oxidizing agent (organic acid component/oxidizing agent) may be within the following range, from the viewpoint of easily polishing the carbon material at a high polishing rate. The mass ratio may be 0.01 or more, 0.05 or more, 0.1 or more, 0.15 or more, or 0.16 or more. The mass ratio may be 1 or less, 0.8 or less, 0.6 or less, 0.5 or less, 0.4 or less, 0.3 or less, or 0.2 or less. From these viewpoints, the mass ratio may be 0.01 to 1, 0.01 to 0.5, 0.01 to 0.3, 0.1 to 1, 0.1 to 0.5, 0.1 to 0.3, 0.15 to 1, 0.15 to 0.5, or 0.15 to 0.3.

The polishing liquid of the present embodiment may contain an organic solvent (excluding compounds corresponding to compounds containing iron ions, an oxidizing agent, or acid components). The polishing rate of a hydrophobic carbon material (for example, a carbon material having a low dielectric constant) may be easily improved by using the organic solvent. In addition, since the decomposition of the oxidizing agent (for example, hydrogen peroxide) is easily inhibited by using the organic solvent, it is easy to polish the carbon material at a high polishing rate.

As the organic solvent, a solvent that is optionally mixed with water can be used. Examples of the organic solvent include carbonate esters such as ethylene carbonate, propylene carbonate, dimethyl carbonate, diethyl carbonate, and methyl ethyl carbonate; lactone compounds such as butyrolactone and propiolactone; glycol compounds such as ethylene glycol, propylene glycol, diethylene glycol, dipropylene glycol, triethylene glycol, and tripropylene glycol; derivatives of glycol compounds including glycol monoethers (for example, glycol monoalkyl ethers) such as ethylene glycol monomethyl ether, propylene glycol monomethyl ether, diethylene glycol monomethyl ether, dipropylene glycol monomethyl ether, triethylene glycol monomethyl ether, tripropylene glycol monomethyl ether, ethylene glycol monoethyl ether, propylene glycol monoethyl ether, diethylene glycol monoethyl ether, dipropylene glycol monoethyl ether, triethylene glycol monoethyl ether, tripropylene glycol monoethyl ether, ethylene glycol monopropyl ether, propylene glycol monopropyl ether, diethylene glycol monopropyl ether, dipropylene glycol monopropyl ether, triethylene glycol monopropyl ether, tripropylene glycol monopropyl ether, ethylene glycol monobutyl ether, propylene glycol monobutyl ether, diethylene glycol monobutyl ether, dipropylene glycol monobutyl ether, triethylene glycol monobutyl ether, and tripropylene glycol monobutyl ether; glycol diethers such as ethylene glycol dimethyl ether, propylene glycol dimethyl ether, diethylene glycol dimethyl ether, dipropylene glycol dimethyl ether, triethylene glycol dimethyl ether, tripropylene glycol dimethyl ether, ethylene glycol diethyl ether, propylene glycol diethyl ether, diethylene glycol diethyl ether, dipropylene glycol diethyl ether, triethylene glycol diethyl ether, tripropylene glycol diethyl ether, ethylene glycol dipropyl ether, propylene glycol dipropyl ether, diethylene glycol dipropyl ether, dipropylene glycol dipropyl ether, triethylene glycol dipropyl ether, tripropylene glycol dipropyl ether, ethylene glycol dibutyl ether, propylene glycol dibutyl ether, diethylene glycol dibutyl ether, dipropylene glycol dibutyl ether, triethylene glycol dibutyl ether, and tripropylene glycol dibutyl ether; ether compounds such as tetrahydrofuran, dioxane, dimethoxyethane, polyethylene oxide, ethylene glycol monomethyl ether acetate, diethylene glycol monoethyl ether acetate, and propylene glycol monomethyl ether acetate; alcohols such as methanol, ethanol, propanol, n-butanol, n-pentanol, n-hexanol, and isopropanol; ketones such as acetone and methyl ethyl ketone; phenol; dimethylformamide; N-methylpyrrolidone; ethyl acetate; ethyl lactate; and sulfolane.

From the viewpoint of easily improving the polishing rate of the hydrophobic carbon material, the organic solvent may include at least one selected from the group consisting of a glycol monoether, an alcohol, and a carbonate ester, may include a glycol monoether, and may include a propylene glycol monopropyl ether.

A content of the organic solvent may be within the following range based on the total mass of the polishing liquid. The content of the organic solvent may be 0.1 mass % or more, 0.2 mass % or more, 0.5 mass % or more, 1 mass % or more, 2 mass % or more, 3 mass % or more, 3.5 mass % or more, or 4 mass % or more, from the viewpoint that sufficient wettability of the polishing liquid with respect to the base substrate is easily obtained, and the polishing rate of the hydrophobic carbon material is easily improved. The content of the organic solvent may be 95 mass % or less, 50 mass % or less, 30 mass % or less, 10 mass % or less, 8 mass % or less, 6 mass % or less, 5 mass % or less, or 4 mass % or less, from the viewpoint of easily improving the polishing rate of the hydrophobic carbon material and the viewpoint of easily reducing the possibility of ignition. From these viewpoints, the content of the organic solvent may be 0.1 to 95 mass %, 0.1 to 50 mass %, 0.1 to 10 mass %, 1 to 95 mass %, 1 to 50 mass %, 1 to 10 mass %, 3 to 95 mass %, 3 to 50 mass %, or 3 to 10 mass %.

The polishing liquid of the present embodiment may contain an additive other than the above-described constituent components. Examples of such an additive include a polymer material.

The polishing liquid of the present embodiment contains water. A content of water in the polishing liquid may be the remainder obtained by excluding the contents of other constituent components from the total amount of the polishing liquid. The content of the water may be 50 mass % or more, 70 mass % or more, 80 mass % or more, or 90 mass % or more based on the total mass of the polishing liquid. The polishing liquid of the present embodiment may be stored as a storage liquid for a polishing liquid having a smaller water content than that at the time of polishing. In this case, the polishing liquid can be obtained by diluting the storage liquid for a polishing liquid with water at the time of polishing.

A pH of the polishing liquid of the present embodiment is 3.5 or less from the viewpoint of polishing the carbon material at a high polishing rate. The pH of the polishing liquid may be 3.3 or less, 3.2 or less, 3.0 or less, 2.8 or less, 2.6 or less, 2.5 or less, 2.4 or less, 2.3 or less, 2.2 or less, 2.1 or less, 2.0 or less, or 1.8 or less, from the viewpoint of easily polishing the carbon material at a high polishing rate. The pH of the polishing liquid may be 1.0 or more, 1.2 or more, 1.5 or more, 1.6 or more, or 1.8 or more, from the viewpoint of easily polishing the carbon material at a high polishing rate. The pH of the polishing liquid may be 2.0 or more, 2.1 or more, 2.2 or more, 2.3 or more, 2.4 or more, 2.5 or more, 2.6 or more, 2.8 or more, or 3.0 or more. From these viewpoints, the pH of the polishing liquid may be 1.0 to 3.5, 1.0 to 3.0, 1.0 to 2.5, 1.0 to 2.0, 1.5 to 3.5, 1.5 to 3.0, 1.5 to 2.5, 1.5 to 2.0, 2.0 to 3.5, 2.0 to 3.0, 2.0 to 2.5, 2.5 to 3.5, or 2.5 to 3.0. The pH of the polishing liquid is defined as the pH at a liquid temperature of 25° C.

The pH of the polishing liquid of the present embodiment can be measured with a pH meter (for example, product name: Model (F-51) manufactured by HORIBA, Ltd.). For example, the pH meter is subjected to three-point calibration using a phthalate pH standard solution (pH: 4.01), a neutral phosphate pH standard solution (pH: 6.86), and a borate pH standard solution (pH: 9.18) as calibration solutions, an electrode of the pH meter is then placed in the polishing liquid, and a value after stabilization for 2 minutes or longer is measured. At this time, the liquid temperatures of the calibration solutions and the polishing liquid are set to 25° C.

A polishing method of the present embodiment includes a polishing step of polishing a carbon material by using the polishing liquid of the present embodiment. In the polishing step, using the polishing liquid of the present embodiment, a surface to be polished, which contains the carbon material, may be polished, and a surface to be polished of a material to be polished, which contains the carbon material, may be polished. In the polishing step, a surface to be polished of a hard mask, which contains the carbon material, may be polished using the polishing liquid of the present embodiment. The polishing liquid used in the polishing step may be a polishing liquid obtained by diluting the storage liquid for a polishing liquid with water. The surface to be polished may have a layer containing at least a carbon material.

In the polishing step, for example, it is possible to polish a surface to be polished by, in a state where the surface to be polished of a base substrate is pressed against a polishing cloth of a polishing platen and a predetermined pressure is applied to the base substrate from a surface opposite to the surface to be polished of the base substrate (a back surface of the base substrate), supplying the polishing liquid of the present embodiment between the surface to be polished of the base substrate and the polishing cloth and moving the base substrate relative to the polishing platen.

As a polishing apparatus, for example, in the case of polishing with the polishing cloth, it is possible to use a general polishing apparatus having a holder capable of holding a base substrate to be polished, and a polishing platen connected to a motor or the like whose rotation speed can be changed and to which the polishing cloth can be attached. As the polishing cloth, a general nonwoven fabric, a foamed polyurethane, a porous fluororesin, or the like can be used, and there is no particular limitation.

The polishing conditions are not limited, but the rotation speed of the polishing platen may be a low rotation of 200 rpm (rpm=min⁻¹) or less so that the base substrate does not pop out. The pressing pressure of the base substrate (semiconductor substrate or the like) having the surface to be polished against the polishing cloth may be 1 to 100 kPa or 5 to 50 kPa, from the viewpoint of easily satisfying uniformity of the polishing rate on the surface to be polished and the flatness of a pattern. During polishing, the polishing liquid can be continuously supplied to the polishing cloth by a pump or the like. The supply amount for this is not limited, and a surface of the polishing cloth may be always covered with the polishing liquid.

In order to carry out polishing (CMP or the like) while maintaining the surface condition of the polishing cloth consistently, a conditioning step of the polishing cloth may be carried out before the polishing. For example, using a dresser with diamond particles, the conditioning of the polishing pad can be performed with a liquid containing at least water. Subsequently, after the polishing method of the present embodiment is carried out, a base substrate cleaning step may be further carried out. After completing the polishing, the base substrate may be thoroughly cleaned in running water, and then dried after removing water droplets adhering to the base substrate using a spin dryer or the like. In addition, drying may be carried out after a known cleaning method (for example, a method of removing substances attached to the base substrate by allowing a commercially available cleaning liquid to flow on the surface of the base substrate and pressing a brush made of polyurethane against the base substrate at a constant pressure while the brush is rotated) is carried out.

A method for manufacturing a component of the present embodiment includes a component preparation step of obtaining a component by using a polished member (a polished member containing a carbon material) polished by the polishing method of the present embodiment. The polished member (the polished member containing a carbon material) polished by the polishing method of the present embodiment may be used as a hard mask. The component of the present embodiment is a component obtained by the method for manufacturing a component of the present embodiment. The component of the present embodiment is not particularly limited, but it may be an electronic component (for example, a semiconductor component such as a semiconductor package), may be a wafer (for example, a semiconductor wafer), and may be a chip (for example, a semiconductor chip). As a form of the method for manufacturing a component of the present embodiment, in a method for manufacturing an electronic component of the present embodiment, an electronic component is obtained using a polished member polished by the polishing method of the present embodiment. As a form of the method for manufacturing a component of the present embodiment, in a method for manufacturing a semiconductor component of the present embodiment, a semiconductor component (for example, a semiconductor package) is obtained using a polished member polished by the polishing method of the present embodiment. The method for manufacturing a component of the present embodiment may include a polishing step of polishing a member to be polished by the polishing method of the present embodiment, before the component preparation step.

The method for manufacturing a component of the present embodiment may include, as a form of the component preparation step, an individually dividing step of individually dividing a polished member (a polished member containing a carbon material) polished by the polishing method of the present embodiment. The individually dividing step may be, for example, a step of dicing a wafer (for example, a semiconductor wafer) polished by the polishing method of the present embodiment to obtain a chip (for example, a semiconductor chip). As a form of the method for manufacturing a component of the present embodiment, the method for manufacturing an electronic component of the present embodiment may include a step of obtaining an electronic component (for example, a semiconductor component) by individually dividing a polished member polished by the polishing method of the present embodiment. As a form of the method for manufacturing a component of the present embodiment, the method for manufacturing a semiconductor component of the present embodiment may include a step of obtaining a semiconductor component (for example, a semiconductor package) by individually dividing a polished member polished by the polishing method of the present embodiment.

The method for manufacturing a component of the present embodiment may include, as a form of the component preparation step, a connection step of connecting (for example, electrically connecting) a polished member (a polished member containing a carbon material) polished by the polishing method of the present embodiment to other body to be connected. The body to be connected to the polished member polished by the polishing method of the present embodiment is not particularly limited, may be a polished member polished by the polishing method of the present embodiment, and may be a body to be connected different from the polished member polished by the polishing method of the present embodiment. In the connection step, the polished member and the body to be connected may be directly connected (connected in a state where the polished member and the body to be connected are in contact with each other), and the polished member and the body to be connected may be connected via other member (conductive member or the like). The connection step can be performed before the individually dividing step, after the individually dividing step, or before and after the individually dividing step.

The connection step may be a step of connecting a polished surface of the polished member polished by the polishing method of the present embodiment to the body to be connected, and may be a step of connecting a connection surface of the polished member polished by the polishing method of the present embodiment to a connection surface of the body to be connected. The connection surface of the polished member may be the polished surface polished by the polishing method of the present embodiment. By the connection step, a connection body having a polished member and a body to be connected can be obtained. In the connection step, in a case where the connection surface of the polished member has a metal portion, the body to be connected may be brought into contact with the metal portion. In the connection step, in a case where the connection surface of the polished member has the metal portion and the connection surface of the body to be connected has the metal portion, the metal portions may be brought into contact with each other. The metal portion may contain copper.

A device (for example, an electronic device such as a semiconductor device) of the present embodiment has at least one selected from the group consisting of a polished member (a polished member containing a carbon material) polished by the polishing method of the present embodiment and a component of the present embodiment.

### EXAMPLES

Hereinafter, the present disclosure will be described in more detail with reference to Examples, but the present disclosure is not limited to these Examples unless departing from the technical idea of the present disclosure.

### Preparation of CMP Polishing Liquid

### Example 1

Malic acid, iron (III) nitrate nonahydrate, and abrasive grains (colloidal silica, average particle diameter: 62 nm) were mixed with deionized water. Subsequently, propylene glycol monopropyl ether and an aqueous solution of 30 mass % hydrogen peroxide were added to obtain a CMP polishing liquid. Based on the total mass of the CMP polishing liquid, a content of the abrasive grains (a content of silica as a solid content) was 0.4 mass %, a content of the iron nitrate nonahydrate was 0.01 mass % (a content of iron ions: 13.8 ppm), a content of the hydrogen peroxide was 3 mass %, a content of the malic acid was 0.5 mass %, and a content of the propylene glycol monopropyl ether was 4 mass %.

### Example 2

A CMP polishing liquid was obtained in the same manner as in Example 1 except that the content of the iron nitrate nonahydrate was changed to 0.02 mass % (the content of iron ions: 27.6 ppm).

### Example 3

A CMP polishing liquid was obtained in the same manner as in Example 1 except that the content of the iron nitrate nonahydrate was changed to 0.1 mass % (the content of iron ions: 138.2 ppm) without using hydrogen peroxide.

### Example 4

A CMP polishing liquid was obtained in the same manner as in Example 1 except that the content of the iron nitrate nonahydrate was changed to 0.1 mass % (the content of iron ions: 138.2 ppm).

### Example 5

A CMP polishing liquid was obtained in the same manner as in Example 1 except that the content of the iron nitrate nonahydrate was changed to 0.1 mass % (the content of iron ions: 138.2 ppm), and the pH of the CMP polishing liquid was changed using a 10 mass % ammonia solution.

### Example 6

A CMP polishing liquid was obtained in the same manner as in Example 1 except that the content of the iron nitrate nonahydrate was changed to 0.2 mass % (the content of iron ions: 276.5 ppm).

### Comparative Example 1

A CMP polishing liquid was obtained in the same manner as in Example 1 except that iron nitrate nonahydrate was not used.

### Comparative Example 2

A CMP polishing liquid was obtained in the same manner as in Example 1 except that the content of the iron nitrate nonahydrate was changed to 0.005 mass % (the content of iron ions: 6.9 ppm).

### Comparative Example 3

A CMP polishing liquid was obtained in the same manner as in Example 1 except that the content of the iron nitrate nonahydrate was changed to 0.1 mass % (the content of iron ions: 138.2 ppm), and the pH of the CMP polishing liquid was changed using a 10 mass % ammonia solution.

### Measurement of Average Particle Diameter of Abrasive Grains

As a result of measuring an average particle diameter of the abrasive grains in the above-described CMP polishing liquid using COULTER N4SD manufactured by Coulter Electronics, Inc., the average particle diameter was 62 nm in all Examples.

### Measurement of pH

The pH of the above-described CMP polishing liquid was measured using “Model (F-51)” (product name) manufactured by HORIBA, Ltd. Specifically, the pH meter was subjected to three-point calibration using a phthalate pH standard solution (pH: 4.01), a neutral phosphate pH standard solution (pH: 6.86), and a borate pH standard solution (pH: 9.18) as calibration solutions, an electrode of the pH meter was then placed in the CMP polishing liquid, and a value after stabilization for 2 minutes or longer was measured. The liquid temperatures of the calibration solutions and the CMP polishing liquid were 25° C. The results are illustrated in Table 1.

### Measurement of Polishing Rate

As a test wafer for evaluation, a base substrate that has a diameter of 12 inches and has an amorphous carbon film (purchased from Global Net Corp., Vickers hardness: 500 HV, a content of carbon atoms: 50 to 80 atm %) having a thickness of 500 nm on a silicon substrate was prepared. The polishing rate of amorphous carbon was measured by polishing (CMP) the above-described test wafer for evaluation by using the above-described CMP polishing liquid under the following polishing conditions.

### Polishing Conditions

Polishing apparatus: “Reflexion LK” (product name) manufactured by Applied Materials, Inc.
Polishing pad: IC1010 (NITTA HAAS INCORPORATED)
Polishing pressure: 20.7 kPa
Platen rotation speed: 93 rpm
Head rotation speed: 87 rpm
Supply amount of CMP polishing liquid: 300 mL/min
Polishing time: 2.0 minutes

The film thickness difference of the amorphous carbon film before and after polishing was measured using an optical film thickness meter (NANOSPECII manufactured by Onto Innovation Inc.), and the polishing rate of the amorphous carbon was calculated based on the film thickness difference and the polishing time. The results are illustrated in Table 1.

TABLE 1

| | | Example | | | | | | Comparative Example | | |
|---|---|---|---|---|---|---|---|---|---|---|
| | Unit | 1 | 2 | 3 | 4 | 5 | 6 | 1 | 2 | 3 |
| Content of | ppm | 13.8 | 27.6 | 138.2 | 138.2 | 138.2 | 276.5 | 0 | 6.9 | 138.2 |
| iron ions | | | | | | | | | | |
| Content of | mass % | 3 | 3 | 0 | 3 | 3 | 3 | 3 | 3 | 3 |
| hydrogen | | | | | | | | | | |
| peroxide | | | | | | | | | | |
| pH | — | 2.4 | 2.2 | 2.1 | 2.1 | 3.0 | 1.8 | 2.4 | 2.4 | 3.9 |
| Polishing rate | nm/min | 0.8 | 1.0 | 1.4 | 1.8 | 0.9 | 2.8 | 0.6 | 0.7 | 0.2 |

1. A CMP polishing liquid for polishing a carbon material, the CMP polishing liquid comprising:
abrasive grains;
iron ions; and
water, wherein
the abrasive grains contain silica,
a content of the iron ions is 7 ppm or more, and
a pH is 3.5 or less.

2. The CMP polishing liquid according to claim 1, wherein the content of the iron ions is 15 to 250 ppm.

3. The CMP polishing liquid according to claim 1, further comprising an oxidizing agent.

4. The CMP polishing liquid according to claim 3, wherein the oxidizing agent includes a peroxide.

5. The CMP polishing liquid according to claim 3, wherein a content of the oxidizing agent is 2 mass % or more.

6. The CMP polishing liquid according to claim 1, further comprising an organic acid component.

7. The CMP polishing liquid according to claim 6, wherein the organic acid component includes at least one selected from the group consisting of a divalent organic acid component and a trivalent organic acid component as an organic acid component having no carbon-carbon unsaturated bond.

8. The CMP polishing liquid according to claim 6, wherein a content of the organic acid component is 0.1 mass % or more.

9. The CMP polishing liquid according to claim 1, further comprising an organic solvent.

10. The CMP polishing liquid according to claim 9, wherein the organic solvent includes a glycol monoether.

11. The CMP polishing liquid according to claim 9, wherein the organic solvent includes a propylene glycol monopropyl ether.

12. The CMP polishing liquid according to claim 1, wherein the carbon material includes amorphous carbon.

13. A polishing method comprising: polishing a carbon material by using the CMP polishing liquid according to claim 1.

14. The CMP polishing liquid according to claim 1, wherein the abrasive grains do not contain zirconia.

15. The CMP polishing liquid according to claim 1, wherein a mass ratio of the content of the iron ions with respect to a content of the abrasive grains is 0.001 to 0.1.

16. The CMP polishing liquid according to claim 1, wherein a mass ratio of the content of the iron ions with respect to a content of the abrasive grains is 0.004 or more.

17. The CMP polishing liquid according to claim 6, wherein the organic acid component includes at least one selected from the group consisting of glutaric acid, adipic acid, malic acid, and salts thereof.

18. The CMP polishing liquid according to claim 9, wherein the organic solvent includes at least one selected from the group consisting of ethylene glycol monomethyl ether, propylene glycol monomethyl ether, dipropylene glycol monomethyl ether, triethylene glycol monomethyl ether, tripropylene glycol monomethyl ether, ethylene glycol monoethyl ether, propylene glycol monoethyl ether, diethylene glycol monoethyl ether, dipropylene glycol monoethyl ether, triethylene glycol monoethyl ether, tripropylene glycol monoethyl ether, ethylene glycol monopropyl ether, propylene glycol monopropyl ether, diethylene glycol monopropyl ether, dipropylene glycol monopropyl ether, triethylene glycol monopropyl ether, tripropylene glycol monopropyl ether, ethylene glycol monobutyl ether, propylene glycol monobutyl ether, diethylene glycol monobutyl ether, dipropylene glycol monobutyl ether, triethylene glycol monobutyl ether, and tripropylene glycol monobutyl ether; glycol diethers such as ethylene glycol dimethyl ether, propylene glycol dimethyl ether, diethylene glycol dimethyl ether, dipropylene glycol dimethyl ether, triethylene glycol dimethyl ether, tripropylene glycol dimethyl ether, ethylene glycol diethyl ether, propylene glycol diethyl ether, diethylene glycol diethyl ether, dipropylene glycol diethyl ether, triethylene glycol diethyl ether, tripropylene glycol diethyl ether, ethylene glycol dipropyl ether, propylene glycol dipropyl ether, diethylene glycol dipropyl ether, dipropylene glycol dipropyl ether, triethylene glycol dipropyl ether, tripropylene glycol dipropyl ether, ethylene glycol dibutyl ether, propylene glycol dibutyl ether, diethylene glycol dibutyl ether, dipropylene glycol dibutyl ether, triethylene glycol dibutyl ether, and tripropylene glycol dibutyl ether

19. The CMP polishing liquid according to claim 9, wherein a content of the organic solvent is 0.1 to 95 mass %.

20. The CMP polishing liquid according to claim 9, wherein a content of the organic solvent is 1 to 10 mass %.
